(19) United States
(12) Patent Application Publication
(10) Pub. No.: US 2016/0116554 A1
(43) Pub. Date: Apr. 28, 2016

(54) NMR PROBE COMPRISING A COIL INCLUDING TWO HELICAL WINDINGS HAVING TURNS OF DIFFERENT OPPOSING ANGLES OF BETWEEN 0 AND 90 DEGREES RELATIVE TO THE AXIS THEREOF

(71) Applicant: COMMISSARIAT A L'ENERGIE ATOMIQUE ET AUX ENERGIES ALTERNATIVES, Paris (FR)

(72) Inventors: Dimitrios SAKELLARIOU, Boulogne-billancourt (FR); Javier ALONSO, Paris (FR)

(21) Appl. No.: 14/779,869

(22) PCT Filed: Mar. 26, 2014
(86) PCT No.: PCT/IB2014/060175

§ 371 Date: Dec. 12, 2015

(30) Foreign Application Priority Data
Mar. 26, 2013 (FR) 1352725

(51) Int. Cl. G01R 33/34

(52) U.S. Cl. CPC G01R 33/34053; G01R 33/34092

(57) ABSTRACT

A probe for nuclear magnetic resonance includes at least one radiofrequency coil (BRF3). The radiofrequency coil includes a first helical winding (E1′″) having turns (S) that are tilted by an angle other than zero and 90° relative to an axis (z) and a second helical winding (E2′″), which is coaxial to the first winding, having turns that are tilted by an angle -a relative to the axis. The helical windings preferably have a length-to-diameter ratio of 1 to 10 and 1 to 25 turns. An apparatus for nuclear magnetic resonance includes the probe. A method for generating a radiofrequency magnetic field uses the radiofrequency coil.

The invention relates to a nuclear magnetic resonance probe and a nuclear magnetic resonance device having a probe of this type. The invention also relates to a radiofrequency coil, specifically for use in a probe of this type, and to a method for the generation of a radiofrequency magnetic field. A coil and a method for the generation of a radiofrequency magnetic field according to the invention may be used in nuclear magnetic resonance applications, but also in other applications including, for example, the containment of plasmas.

In general, “radiofrequency” is understood as any frequency between 3 kHz and 300 GHz, more specifically any frequency between 300 kHz and 3 GHz and, more specifically again, any frequency between 1 MHz and 1 GHz.

A “nuclear magnetic resonance device” is understood as a spectroscopic device operating by nuclear magnetic resonance (NMR) and/or a nuclear magnetic resonance imaging (MRI) device.

A “nuclear magnetic resonance probe” is understood as the part of a nuclear magnetic resonance device which is designed to generate a radiofrequency magnetic field for the excitation of the nuclear spins in a sample and/or for the detection of a radiofrequency magnetic field emitted by the de-excitation of said nuclear spins. A probe of this type generally comprises a resonant circuit of the LC type, incorporating a coil which is responsible for coupling with an external radiofrequency magnetic field, together with an adaptive impedance matching circuit.

A “coil” is understood as an element comprising one or more windings of a wire, cable or strip conductor. A “winding” is understood as a combination of turns or loops of the same wire, cable or strip conductor, with no short-circuits.

The superconducting magnets used in NMR and MRI experiments have a cylindrical geometry and generate a generally stationary magnetic field which is oriented in the longitudinal axis of the cylinder (the “axial”, “longitudinal” or “main” magnetic field). This magnetic field polarizes the nuclear spins of the atoms in the sample under analysis. This means that there is a population difference (generally described as “polarization”) between the upper and lower Zeeman energy levels. Transitions between these levels are excited using a radiofrequency (RF) magnetic field which is perpendicular to the axial magnetic field; as a variant, an RF magnetic field is used to excite the magnetization of the sample.

Antennae (coils) of appropriate design generate an RF magnetic field of this type, the orientation of which may not be perpendicular to the axial magnetic field but which must, by definition, include a perpendicular component. The larger the perpendicular component of the RF field per unit of current, the greater the efficiency of excitation and, reciprocally, the higher the signal-to-noise ratio (SNR) of the magnetic resonance signal this is described as the “sensitivity” of the coil. The spatial uniformity (homogeneity) of the RF field on the interior of the coil is also very important in NMR experiments, and may be crucial in MRI experiments.

The most widespread type of antenna, which delivers the best performance in terms of the intensity and homogeneity of the RF field, is a simple solenoid coil, with a single winding. However, a coil of this type generates a magnetic field which is parallel to its axis, and must therefore be arranged perpendicularly to the main magnetic field. This means that the sample cannot be inserted “at the top end” of the superconducting magnet (i.e. in an axial direction) and cannot be rotated around the longitudinal axis. However, such rotation of the sample is very useful for the improvement of NMR spectroscopic resolution, specifically in the case of a liquid sample.

Other commonly-used types of RF coils include Helmholtz coil pairs or saddle coils, although these show an inferior RF field performance. The main advantage of the saddle coil is that it is wound on a cylindrical surface and can generate an RF magnetic field which is oriented perpendicularly to the axis of this cylinder. The axis of a coil of this type can therefore be aligned with the direction of the main magnetic field, thereby permitting the insertion of the sample in this direction and the rotation thereof around the latter. Although its sensitivity is inferior to that of a solenoid coil, a saddle coil delivers a reasonably satisfactory spatial homogeneity, and provides a certain ease of use. For these reasons, the saddle coil is the most commonly used type in NMR experiments involving the liquid state. This type of coil also shows a low inductance and reduced resistance in comparison with other types of coils, which is beneficial for high-frequency applications.

In MRI systems, different coil geometries are used to generate a magnetic field which is perpendicular to the longitudinal axis of the system (and consequently to the main magnetic field). Examples include, but not by way of limitation, birdcage coils and Alderman-Grant coils. These provide larger volumes of homogeneity, to the detriment of sensitivity and at the cost of higher inductance.

The invention is intended to overcome the above-mentioned disadvantages of the prior art.

More specifically, the invention is intended to provide a nuclear magnetic resonance probe which shows high sensitivity and a high degree of homogeneity in the radiofrequency magnetic field, whilst permitting the insertion of the sample in a parallel direction to the longitudinal axis of the system, and a nuclear magnetic resonance device (NMR or MRI) provided with a probe of this type.

The invention is also intended to provide a coil which permits the efficient generation of a highly homogeneous radiofrequency magnetic field which shows a perpendicular orientation to the axis of said coil. Specifically, a coil of this type may be used in a probe according to the invention.

The invention is also intended to provide an efficient method for the generation of a highly homogeneous radiofrequency magnetic field, whilst permitting access to the spatial region in which said field is located from a perpendicular direction to the latter. A method of this type can specifically be deployed by means of a coil or a probe according to the invention.

A basic concept of the invention involves the use of one or more coils comprising two helical windings, the turns of which show different angles of inclination relative to a common longitudinal axis. Coils with a structure of this type are known from the prior art as “double helix dipoles” (or DHDs), c.f.:
A. Akhmeteli, A. Gavrilin and W. Marshall, “Superconducting and resistive tilted coil magnets for generation of high and uniform transverse magnetic field”, IEEE Transactions on Applied Superconductivity, 15, 1439-1443 (2005);
C. Goodzeit, M. Ball and R. Meinke, “The Double-Helix Dipole. A Novel Approach to Accelerator Magnet Design”, IEEE Transactions on Applied Superconductivity, 13, 1365-1368 (2003);
U.S. Pat. No. 6,921,042;
S. Farinon and P. Fabbricatore, “Refined modeling of superconducting double helical coils using finite element analysis”, Supercond. Sci. Technol. 25 (2012).

However, these coils which are known from the prior art have a very large number of turns per winding (48 in the above-mentioned article by S. Farinon and P. Fabbricatore), by way of justification for the approximation of infinite length. Consequently, they show a high inductance, which precludes the operation thereof at radiofrequencies (in practice, these coils are supplied with direct current for the generation of static magnetic fields), and occupy a large volume, which renders them impractical for use in nuclear magnetic resonance applications. The present inventors have discovered, unexpectedly, that coils with a tilted double helix structure can be dimensioned in order to permit the use thereof at radiofrequencies and in a confined environment.

One object of the invention is therefore a probe comprising at least one radiofrequency coil, characterized in that said radiofrequency coil comprises a first helical winding, having turns that are tilted by an angle a other than zero and 90° relative to an axis, and a second helical winding which is coaxial to said first winding, having turns that are tilted by an angle −α relative to said axis.

According to the advantageous modes of embodiment:
A probe of this type may comprise at least two said radiofrequency coils, arranged coaxially, the windings of which are oriented such that the planes formed by the axes of their turns and the common axis of the two coils are mutually perpendicular.
The turns of said coil or of each said coil may be tilted by an angle of between 10° and 50°.
Each said helical winding may be provided with a number of turns ranging from 1 to 25.
The helical windings of any one coil may be connected in series, such that the same current flows therein.
Said helical windings may be provided with the same number of turns.

A further object of the invention is a nuclear magnetic resonance device comprising:
a magnet for the generation, in a said interior volume, of a stationary magnetic field oriented in a said longitudinal direction;
a probe according to one of the above claims, arranged in said interior volume; and
a radiofrequency generator supplying the coil of said probe.

According to a first mode of embodiment of a nuclear magnetic resonance device of this type, said probe may comprise one or more coils, the axis of which is parallel to said longitudinal direction of said stationary magnetic field.

According to a second mode of embodiment of a nuclear magnetic resonance device of this type, said probe may comprise one or more coils, the axis of which is tilted by an angle φ_{M}=arctan(√2) (“magic angle”) in relation to said longitudinal direction of said stationary magnetic field.

A further object of the invention is a coil comprising a first helical winding, having turns that are tilted by an angle α other than zero and 90° relative to an axis, and a second helical winding which is coaxial to said first winding, having turns that are tilted by an angle −α relative to said axis, characterized in that said helical windings have a number of turns between 1 and 25. Advantageously, each said helical winding may be provided with the same number of turns.

A further object of the invention is a method for the generation of a radiofrequency magnetic field involving the supply, by a radiofrequency current source, of a coil comprising a first helical winding, having turns that are tilted by an angle α other than zero and 90° relative to an axis, and a second helical winding which is coaxial to said first winding, having turns that are tilted by an angle −α relative to said axis.

According to the advantageous modes of embodiment of a method of this type:
Said angle a may be between 10° and 50°.
Each said helical winding may be provided with a number of turns between 1 and 25.
Said helical windings may be provided with an equal number of turns and connected in series, such that the same current flows therein.

Further characteristics, details and advantages of the invention are disclosed in the description, which refers to the attached drawings, provided by way of example, and in which, respectively:

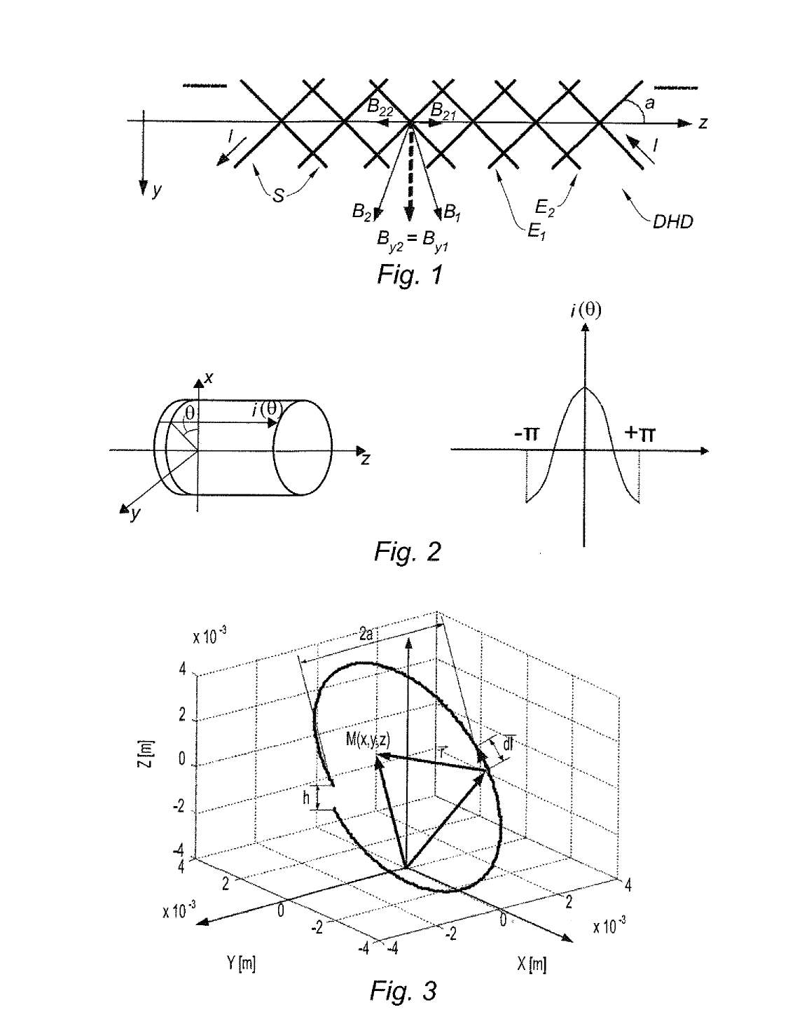

FIG. 1 shows a double helix dipole;

FIG. 2 shows a current distribution for the production of a magnetic field of maximum homogeneity;

FIG. 3 shows a tilted turn;

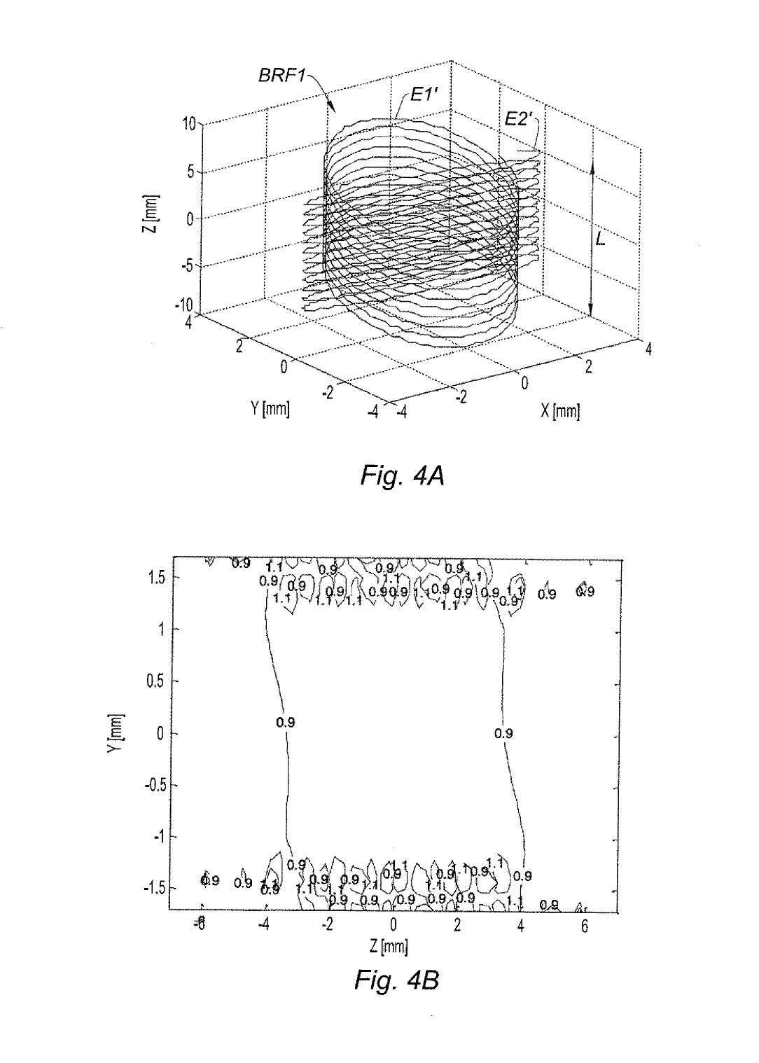

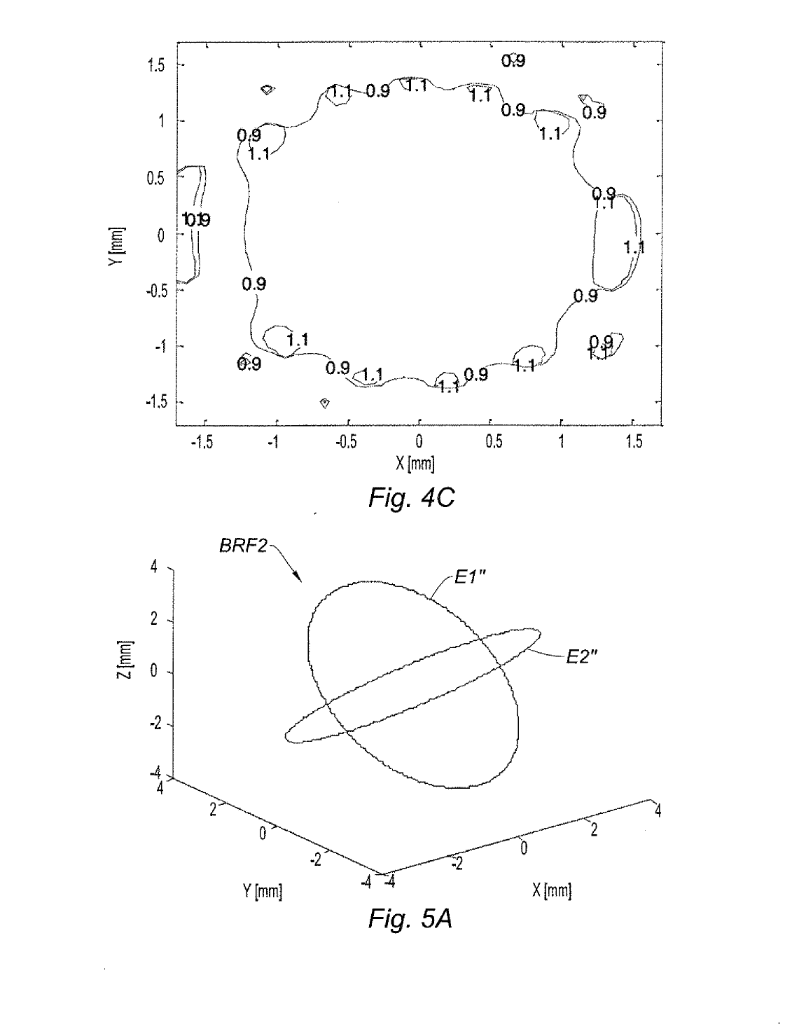

FIG. 4A shows a radiofrequency coil according to a first mode of embodiment of the invention;

FIGS. 4B and 4C show contour plots illustrating the magnetic flux generated by the coil in FIG. 4A;

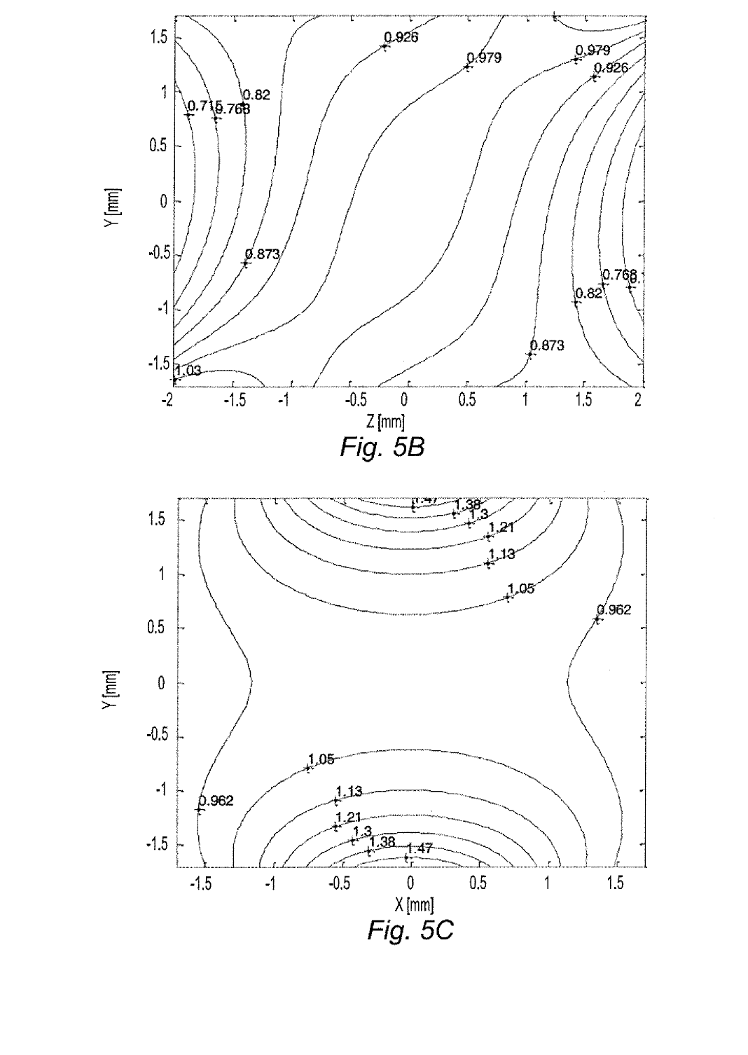

FIG. 5A shows a radiofrequency coil according to a second mode of embodiment of the invention;

FIGS. 5B and 5C show contour plots illustrating the magnetic flux generated by the coil in FIG. 5A;

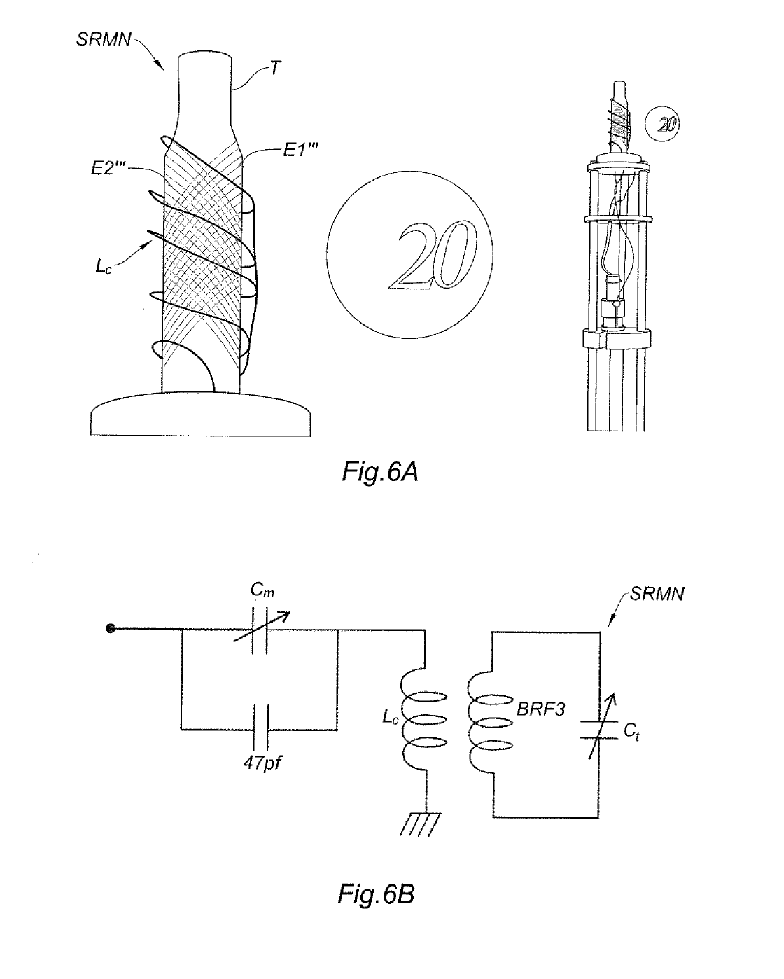

FIGS. 6A and 6B, respectively, show a nuclear magnetic resonance probe according to a third mode of embodiment of the invention, and its adaptive circuit;

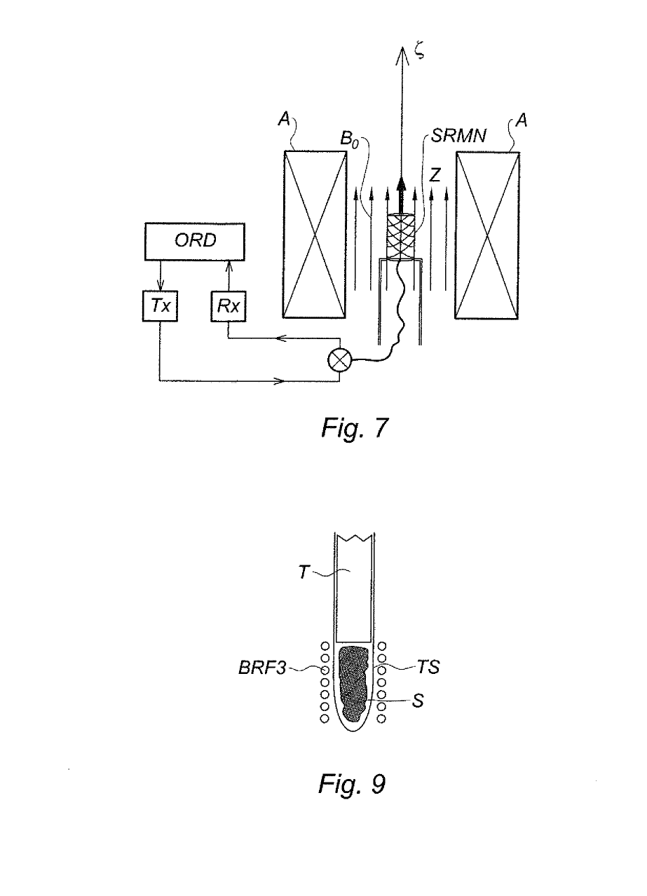

FIG. 7 shows a NMR device using a probe of this type;

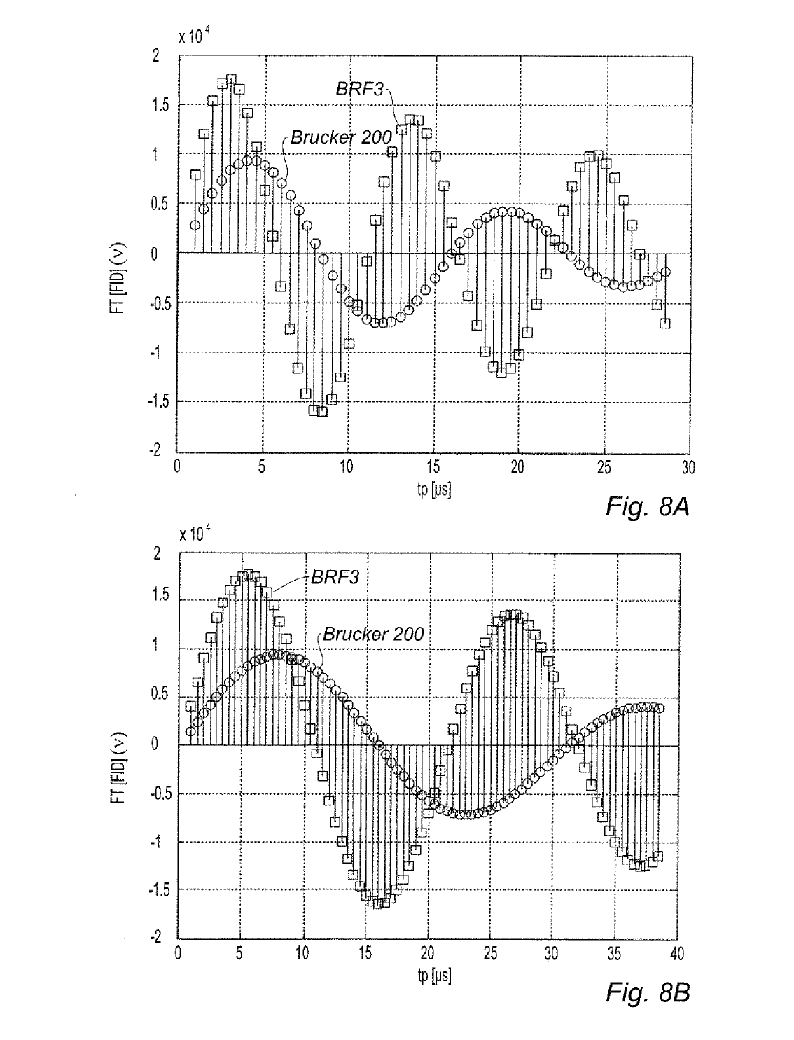

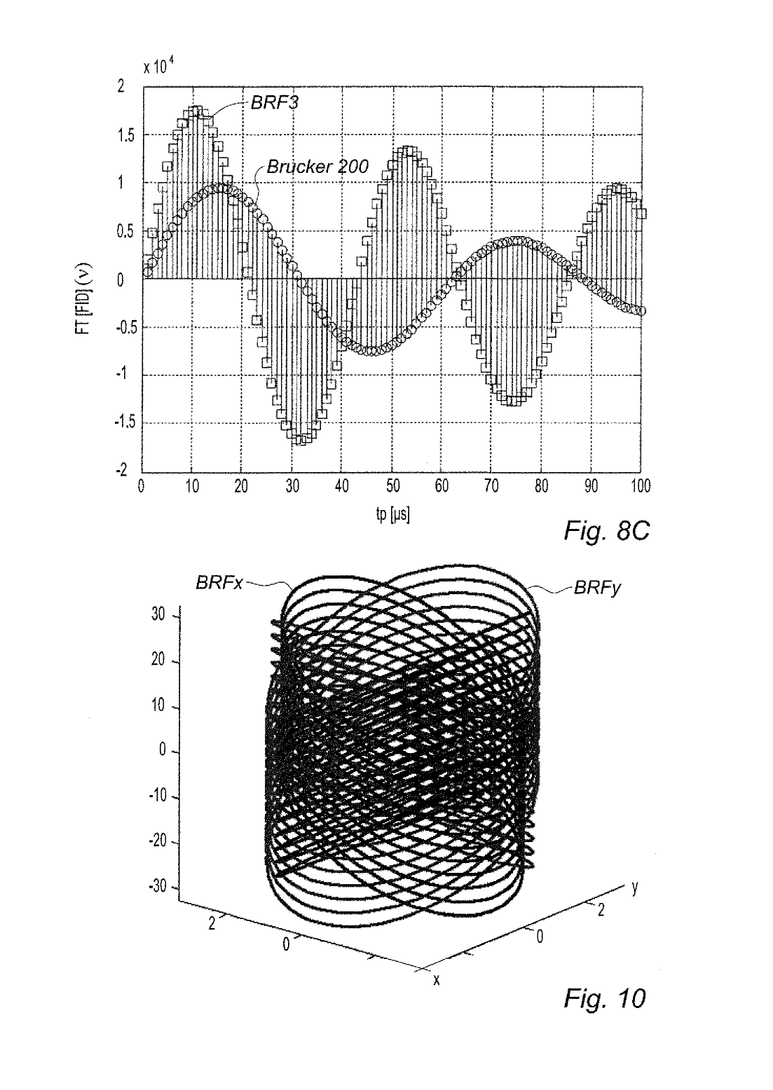

FIGS. 8A-8C show the results of an NMR experiment which demonstrate the technical advantage of the invention over a probe according to the prior art;

FIG. 9 shows the arrangement of a sample inside a probe according to said third mode of embodiment of the invention; and

FIG. 10 shows a radiofrequency coil according to a fourth mode of embodiment of the invention.

Before embarking upon a detailed description of the invention, it is appropriate to review the theory of double helix dipoles.

As represented schematically in FIG. 1, a DHD magnetic dipole of this type is a coil comprised of two superimposed solenoidal windings E1 and E2, considered to be of infinite length, the turns S of which are tilted respectively by an angle +α and −α relative to a z-axis. Conversely to an “ordinary” solenoid, in which the turns are perpendicular to the axis, in a double helix dipole the angle α is significantly different from 90° and 0°, and is often close to 45°.

When traversed by an electric current, each winding generates a magnetic field B₁, B₂, comprising a longitudinal (solenoidal) component B_{z1}, B_{z2}, and a transverse (dipolar) component B_{z1}, B_{z2}. If the windings are identical and are traversed by the same electric current, B_{z2}=−B^{z1}, and B_{z2}=B_{z1}; in other words, the longitudinal components cancel each other out, whereas the transverse components are combined, such that the resulting field is purely transverse. By varying the ratio between the currents flowing in the two windings, it is possible to modify the orientation of the resulting magnetic field, between a purely longitudinal orientation and a purely transverse orientation.

It can be demonstrated that, in the case of a DHD coil of infinite length, the transverse magnetic field on the interior of the coil is perfectly homogeneous (not dependent upon the distance from the z-axis), where the electric current is dependent upon the azimuth angle θ (polar coordinate in a perpendicular plane to the axial direction z) in accordance with a cosine law: i(θ)=I₀ cos(θ), where I₀ is the total current flowing in the coil. As demonstrated in the above-mentioned article by A. Akhmeteli et al., whereby each of the two windings E1, E2 of the DHD coil in FIG. 1 may be described by a current density, the longitudinal component J_{z}, of which is precisely governed by a law of the following type:

$${J}_{z} = {I}_{0} \frac{a cos θ + h / 2 π}{ahd tan α} = {J}_{z} ( θ ) + {J}_{z}^{sol}$$

where a is the radius of the winding, h is its pitch and d is the diameter of the wire. This situation is illustrated in FIG. 2. The term J_{z}^{sol} is responsible for the solenoidal magnetic field, i.e. the field oriented in the axis of the coil. The longitudinal solenoidal magnetic fields of the two windings of the coil cancel each other out, such that the value of J_{z}^{sol} is therefore of little significance.

Here again, it should be noted that this result is based upon the assumption of a winding of “infinite” length in relation to its radius, comprised of an “infinite” number of turns. However, a coil comprising windings of this type would have an extremely high inductance and could not, in practice, be used in radiofrequency applications, specifically in a nuclear magnetic resonance probe, which must be resonant at a frequency which is generally of the order of several MHz.

The present inventors have therefore considered the case of a coil having a structure which is analogous to that of a DHD dipole but of finite length, having a limited number of turns, and consequently of sufficiently low inductance to permit the use thereof in radiofrequency applications (and of sufficiently small volume to permit the use thereof in a nuclear magnetic resonance probe). The analysis of a coil of this type must commence with the consideration of the case of an isolated turn S, represented on FIG. 3. As explained above, a=2.5 mm represents the radius of the cylinder upon which the turn is wound, and consequently the minor semiaxis of the turn, which is elliptical in shape as a result of its inclination in relation to the axis of said cylinder, and h=1 mm represents its pitch, i.e. the distance between its ends in the direction z. The turn is tilted at an angle α=35.3° relative to said direction z. The Biot-Savart law permits the calculation of the magnetic flux density B at point M (x,y,z) as follows:

$$B ( x , y , z ) = \frac{{μ}_{0} I}{4 π} ∮ \frac{\overline{d} l \times \vec{r}}{{r}^{2}}$$

where I is the electric current, dl is the element of length of the turn and r^{→} is the vector connecting a point on the turn to point M. For the execution of this calculation, it is appropriate to apply the parametric expression of the turn (and consequently of the integration path) in relation to the angle θ:

$$x ( θ ) = a cos θ$$

$$y ( θ ) = a sin θ$$

$$z ( θ ) = \frac{h}{2 π} θ + \frac{a sin θ}{tan a} = \frac{h}{2 π} θ + acot ( α ) sin ( θ )$$

The magnetic flux generated by a winding comprised of N>1 turns is determined in the same way, simply by varying the angle θ between 0 and 2Nπ. In consideration of the effects of a second winding, which is coaxial to the first, arranged around the latter and having turns at an opposing angle (−α), this gives the following:

$$B ( x , y , z ) = \frac{{μ}_{0} {I}_{1}}{4 π} ∮ \frac{\overline{d {l}_{1}} \times {\vec{r}}_{1}}{{r}_{1}^{2}} - \frac{{μ}_{0} {I}_{1}}{4 π} ∮ \frac{\overline{d {l}_{2}} \times {\vec{r}}_{2}}{{r}_{2}^{2}}$$

where the indices “1” and “2” designate the first and the second winding respectively.

The above equation permits the numerical calculation of the magnetic field at any point in the interior of the coil (or even on the exterior of the coil, although this calculation is of less benefit).

FIG. 4A shows a radiofrequency coil BRF1 according to a first mode of embodiment of the invention. The coil is of length L=12 mm and is comprised of two windings of 12 turns wound on a cylinder of radius a=2.5 mm with a tilt of ±35.3° (which confers an elliptical form thereupon, even if said cylinder is of circular cross-section), and of pitch h=1 mm. The two windings E1′, E2′ are traversed by the same current, which can be achieved by the mutual connection thereof in series and the connection thereof to the same current generator. The ratio of length to diameter (the diameter of the coil is considered or, in an equivalent manner, the diameter of the windings, rather than that of each turn considered individually) is L/(2a.sinα)≈4.15, which is very substantially removed from the approximation of infinite length upon which the theory of double helix dipoles is based. More generally, the length/diameter ratio of a coil according to the invention is advantageously comprised between 1 and 10, preferably between 2 and 5, and more preferably still between 2 and 3.

As a variant, the two windings may be supplied by separate and independent current generators. As explained above, this permits the adjustment of the orientation of the radiofrequency magnetic field.

FIGS. 4B and 4C show contour plots of the magnetic flux generated by said coil, standardized to its central value (at point x=0, y=0, z=0), in plane YZ and plane XY respectively.

The magnetic flux component in direction y assumes a maximum value of 1.9 T/mA, whereas the remaining components are lower by at least one order of magnitude, thereby indicating that the magnetic field is essentially transverse. Virtually perfect homogeneity is achieved throughout the interior volume of the coil, at the level of superimposition of the two windings. The inductance of the coil may also be calculated numerically: the resulting value is approximately 1.06 μH, which is suitable for magnetic resonance applications with a “low” Larmor frequency, i.e. frequencies ranging from 20 MHz to 200 MHz for ¹H spectra.

FIG. 5A shows a radiofrequency coil BRF2 according to a further mode of embodiment of the invention, which is suitable for higher frequency applications. In this coil, each of the windings E1′, E2″ is comprised of a single elliptical turn, formed by a conductive wire of diameter 0.25 mm. The turn of winding E1″ has a long axis of 3.8 mm and a short axis of 2.5 mm; the turn of winding E2″, arranged around the above, has a long axis of 4.5 mm and a short axis of 3 mm. Given an angle α of 33.5°, the length L of the coil is approximately 5 mm and its largest transverse dimension is 3 mm, giving an aspect ratio (ratio of length to the largest transverse dimension) of 1.7.

FIGS. 5B and 5C show contour plots of the magnetic flux generated by said coil, standardized to its central value (at point x=0, y=0, z=0), in plane YZ and plane XY respectively. The region of homogeneity of the field can be identified as a cylinder of axis z and of approximate volume 43 mm³. The region of homogeneity is defined as the region within which the intensity of the magnetic field varies by a maximum of ±0.5% in relation to its value at the center of the coil. The magnetic flux component in direction y assumes a maximum value of 0.28 T/mA, and the inductance of the coil is approximately 35 nH, which is appropriate for operation at high frequency (of the order of 500 MHz).

By way of comparison, a saddle coil of identical interior volume, in which the diameter and the length of the wire are selected such that the resulting electrical resistance is also identical, permits the achievement of a region of homogeneity of similar volume, but with a transverse magnetic flux component of only 0.017 mT/A. This means that, in order to deliver the same magnetic field intensity, the saddle coil (with inductance of the order of 20 nH) requires a supply current which is approximately 16 times greater than that required by a coil according to the invention.

FIG. 6A shows two views of a probe SRMN for magnetic resonance applications, according to one mode of embodiment of the invention. The probe comprises a coil BRF3 comprised of two windings E1′″, E2′″, each having 13 turns of a conductive wire of diameter 0.4, wherein the diameter of the coil is 7 mm, the tilt angle of the turns is ±35.3°, the inductance is 1.3 μH, the direct current resistance R_{dc}=0.0719Ω, and the length of the region of superimposition of the two windings is 17 mm; the total length of the conductive wire is 528 mm. The coil is housed on the interior of a glass tube T, mounted on a structure of rods ST which permits the insertion thereof into an NMR spectrometer; the distal end of the tube (opposite the structure of rods) is open in order to permit the insertion of a sample. The probe is also provided with an adaptive impedance matching circuit, comprising the following: a tuning capacitor Cₜ, having an adjustable capacitance from 1 pF to 10 pF, an inductive coupling L_{c} (winding around the tube) and an adaptive impedance matching capacitor Cₘ, having an adjustable capacitance from 3 pF to 23 pF, connected in parallel with a capacitor of 47 pF. This circuit, the electric circuit layout of which is shown in FIG. 6B, permits an effective adaptive matching of impedance within the range of 29 MHz to 41 MHz. The 20 centime coin (euro) represented next to the probe gives an idea of the dimensions of the latter.

FIG. 7 represents a probe of this type inserted in a nuclear magnetic resonance (NMR) spectroscopic device comprising a magnet A for the generation of a longitudinal magnetic field B₀, a transmission circuit Tx (generally comprising a signal generator, an emitter and a radiofrequency amplifier), a reception circuit Rx (generally comprising a pre-amplifier, a receiver and an analog-digital converter), and a computer ORD. The transmission circuit Tx uses the probe SRMN as an emitting antenna, for the generation of the radiofrequency magnetic field which excites the nuclear spins of the protons in a sample arranged on the interior of the coil. The reception circuit Rx uses said probe as a receiving antenna for the detection of the nuclear magnetic resonance signal emitted by said nuclear spins. The computer ORD controls said circuits and is responsible for the processing of the signals acquired.

In the example shown in FIG. 7, the z-axis of the coil is parallel to the direction of the magnetic field B (indicated on the diagram by ζ). In general, however, the z-and ζ-axes may form an arbitrary angle. The use of a probe, the coil of which is not aligned in the direction ζ may be advantageous, specifically to permit the rotation of the sample to the “magic angle”, using a technique which will be familiar to the specialist. In this specific case, the angle formed by the z-and ζ-axes must observe the relationship φ_{M}=arctan(√2).

The probe described above has been used in a simple nuclear magnetic resonance experiment, in order to permit the appraisal of the performance characteristics thereof-specifically the duration of a 90° pulse and the homogeneity of the field-and the comparison of these performance characteristics with those of a commercial probe comprising a saddle coil. The experiment has been conducted in a constant longitudinal magnetic field of 0.887 T, corresponding to a Larmor frequency ν=37.3 MHz for ₁H. The sample S used was a solution of H₂O and Cu₂SO₄, diluted in order to minimize the relaxation time T₁, placed in a Shigemi tube TS with a sample length of approximately 13 mm; this arrangement is illustrated in FIG. 9. Nutation measurements were completed for three radiofrequency excitation power levels: 5 W, 2 W and 0.5 W. For comparative purposes, measurements were repeated using a commercial Bruker 200 probe, comprising a saddle coil of length 13 mm (in comparison with the 17 mm length of the coil according to the invention). FIGS. 8A, 8B and 8C-for the excitation power levels SW, 2 W and 0.5 W respectively, show the peak intensity of the FID signal (more specifically, the Fourier transform of the FID signal, expressed as a function of the frequency ν) detected at the Larmor frequency, as a function of the duration of the excitation pulse tp; on these diagrams, the circles correspond to the values measured using the Bruker 200 reference probe, and the squares to those obtained using the probe according to the invention. The first maximum value of the signal permits the identification of the value of tp which corresponds to a 90° pulse: it will be noted that this value is lower for the probe according to the invention, thereby confirming that the latter is of higher efficiency (ratio of the magnetic field intensity to the intensity of the supply current) than the commercial probe. The ratio between the first and the second maximum values of the signal provides a measure of the inhomogeneity of the radiofrequency magnetic field: a ratio of approximately 1 would indicate perfect homogeneity, and the smaller the ratio, the higher the degree of homogeneity. This indirect and qualitative measure of homogeneity is applied on the grounds that the mapping of the magnetic field on the interior of the coil would be extremely difficult, as a result of its small dimensions. In any event, it can be confirmed that the probe according to the invention permits the achievement of a more homogeneous field than the commercial probe.

A probe according to the invention is therefore particularly advantageous for nuclear magnetic resonance applications at “low frequencies” (20-200 MHz). A probe of this type is particularly suitable for the analysis of liquid samples, and for the deployment of techniques including the above-mentioned technique of magic angle spinning.

The invention accommodates a number of variants.

For example, the number of coils may be greater than two, as in the case of the DHD coil described in the above-mentioned article by A. Akhmeteli et al. Likewise, the two windings may comprise a different number of turns, provided that the electric currents flowing therein are adjusted accordingly.

The length/diameter ratio of the coil in a probe according to the invention may be lower than 1 or greater than 10—the only critical factor is that its inductance should be sufficiently low to permit its use in radiofrequency applications.

Although consideration has been restricted thus far to coils of circular or elliptical cross-section, this is not essential; for example, coils of polygonal cross-section might be envisaged.

Coils according to the invention may be used in probes of different structure to that described. Specifically, in an alternative mode of embodiment illustrated in FIG. 10, the probe comprises two coaxial coils BRFx (shown on the diagram in black) and BRFy (shown in grey), each having two windings respectively. The turns of the internal coil, BRFx, are tilted relative to the x- and z-axes, such that the radiofrequency field generated is oriented in the direction x (or, more generally, in a direction which lies in the x-z plane). The external coil, BRFy, is provided with a structure which is rotated by 90° around the z-axis, and the turns are therefore tilted relative to the y- and z-axes, such that the radiofrequency field generated is oriented in the direction y (or, more generally, in a direction which lies in the y-z plane). In other words, the plane formed by the axes of the turns of coil BRFx and the z-axis is orthogonal to the plane formed by the axes of the turns of coil BRFy and said same z-axis.

Advantageously, the two coils are identical, except in that they are provided with slightly different diameters, for reasons of mechanical spatial requirements (for example, in the case shown in FIG. 10, coil BRFx has an external diameter of 5.2 mm and coil BRFy, which is arranged on the exterior of the latter, has an exterior diameter of 5.6 mm). In addition, said coils are advantageously supplied by electric currents in quadrature, such that the radiofrequency magnetic fields generated are also in quadrature (i.e. with a temporal offset of one quarter-cycle) and show orthogonal spatial orientations, both mutually and relative to the axis of the coil. This permits the improvement of the signal-to-noise ratio by a factor of √2. A mode of embodiment might also be envisaged in which the two coils generate transverse fields, between which an angle of less than 90° is formed, although this is generally less advantageous.

1. A nuclear magnetic resonance probe comprising at least one radiofrequency coil, said radiofrequency coil comprises a first helical winding, having turns that are tilted by an angle α other than zero and 90° relative to an axis, and a second helical winding which is coaxial to said first winding, having turns that are tilted by an angle −α relative to said axis.

2. The probe according to claim 1, comprising at least two said radiofrequency coils, arranged coaxially, the windings of which are oriented such that the planes formed by axes of their turns and a common axis of the two coils are mutually perpendicular.

3. The probe according to claim 1, wherein the turns of said coil or of each said coil are tilted by an angle of between 10° and 50°.

4. The probe according to claim 1, wherein each said helical winding is provided with a plurality of turns ranging from 1 to 25.

5. The probe according to claim 1, wherein the helical windings of any one coil are connected in series, such that a same current flows therein.

6. The probe according to claim 1, wherein said helical windings are provided with the same number of turns.

7. A nuclear magnetic resonance device, comprising:
a magnet for generation, in an interior volume, of a stationary magnetic field oriented in a longitudinal direction;
a probe according to claim 1, arranged in said interior volume; and
a radiofrequency generator supplying the coil of said probe.

8. The nuclear magnetic resonance device as claimed in claim 7, wherein said probe comprises one or more coils, the axis of which is parallel to said longitudinal direction of said stationary magnetic field.

9. The nuclear magnetic resonance device as claimed in claim 7, wherein said probe comprises one or more coils, the axis of which is tilted by an angle φ_{M}−arctan(√2) in relation to said longitudinal direction of said stationary magnetic field.

10. A coil comprising a first helical winding, having turns that are tilted by an angle α other than zero and 90° relative to an axis, and a second helical winding which is coaxial to said first winding, having turns that are tilted by an angle −α relative to said axis, said helical windings having between 1 and 25 turns.

11. The coil as claimed in claim 10, wherein each said helical winding is provided with the same number of turns.

12. A method for generation of a radiofrequency magnetic field involving the supply, by a radiofrequency current source, of a coil comprising a first helical winding, having turns that are tilted by an angle α other than zero and 90° relative to an axis, and a second helical winding which is coaxial to said first winding, having turns that are tilted by an angle −α relative to said axis.

13. The method as claimed in claim 12, wherein said angle α is between 10° and 50°.

14. The method according to claim 12, wherein each said helical winding is provided with between 1 and 25 turns.

15. The method according to claim 12, wherein said helical windings are provided with an equal number of turns and connected in series, such that a same current flows therein.
